(19) United States
(12) Patent Application Publication
(10) Pub. No.: US 2009/0272661 A1
(43) Pub. Date: Nov. 5, 2009

(54) MULTI-FUNCTIONAL BOX FOR NOTEBOOK COMPUTER

(76) Inventor: Jan-Ban Liu, Taipei County (TW)

Correspondence Address: Jan-Ban Liu, 235 Chung - Ho Box 8-24, Taipei, 235, TW

(21) Appl. No.: 12/113,213

(22) Filed: May 1, 2008

(51) Int. Cl. B65D 85/00; H05K 5/00

(52) U.S. Cl. 206/320

(57) ABSTRACT

A multi-functional box for a notebook computer comprises a first cover and a second cover which are pivotally connected as a combining structure; at least one receiving groove formed in a top inner side of each of the first cover and second cover; each receiving groove being covered by a covering plate for isolating the receiving grooves of the first cover and second cover; a supporting plate installed at a topside of the first cover; each of two lateral sides of the supporting plate being installed with a connecting rod which rests in a slot of a positioning strip for adjusting an orientation of a display screen of a notebook computer; at least one buckle for combining the first cover and second cover at tops of the first cover and cover; and at least on stop sheet installed to a recess of the first cover.

### FIELD OF THE INVENTION

The present invention relates to receiving of notebook computers, and particularly to a multi-functional box for a notebook computer.

### BACKGROUND OF THE INVENTION

Generally, a notebook computer can be received in a bag for being carried out. The notebook computer is taken out to place upon legs or a table for using. Commercially, as in the state of no table, the notebook computer is often placed upon the legs of user, but this will induce that the heat from the notebook computer will transfer to the legs so that the user will feel uneasy. Furthermore, generally the bag for receiving a notebook computer has no the function of protection.

Thus, there is an eager demand for a novel multi-functional box for receiving a notebook computer which can improve the defects in the prior art.

### SUMMARY OF THE INVENTION

Accordingly, the object of the present invention is to provide a multi-functional box for a notebook computer, which has a handle and a belt and is made of concrete material. The interior thereof is disposed with impact-proof sponge so as to prevent the notebook computer from damage due to collision. The box is further installed with a supporting plate for adjusting an angle of a display screen of a notebook computer. Furthermore, a mouse pad is installed in the box. The mouse pad can be pulled out for locating a mouse.

To achieve above object, the present invention provides a multi-functional box for a notebook computer, comprising: a first cover and a second cover which are pivotally connected as a combining structure; at least one receiving groove formed in a top inner side of each of the first cover and second cover; each receiving groove being covered by a covering plate for isolating the receiving grooves of the first cover and second cover; the receiving grooves of the first cover spaced for receiving different objects including signal wires, USP expanders, earphones, microphones; and the receiving grooves of the second cover being spaced for receiving different objects including transformers, power wires, mice; a supporting plate installed at a topside of the first cover; each of two lateral sides of the supporting plate being installed with a connecting rod which rests in a slot of a positioning strip for adjusting an orientation of a display screen of a notebook computer; at least one buckle for combining the first cover and second cover at tops of the first cover and cover; and at least on stop sheet installed to a recess of the first cover.

The various objects and advantages of the present invention will be more readily understood from the following detailed description when read in conjunction with the appended drawing.

### BRIEF DESCRIPTION OF THE DRAWINGS

FIG. 1 is an explosive schematic view of the present invention.

FIG. 2 is another explosive schematic view of the present invention.

FIG. 3 is an assembled schematic view of the present invention.

FIG. 4 is an assembled schematic view showing that the present invention is installed with a belt.

FIG. 5 is a schematic view showing the operation of the present invention.

FIG. 6 is a schematic view showing a preferred embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

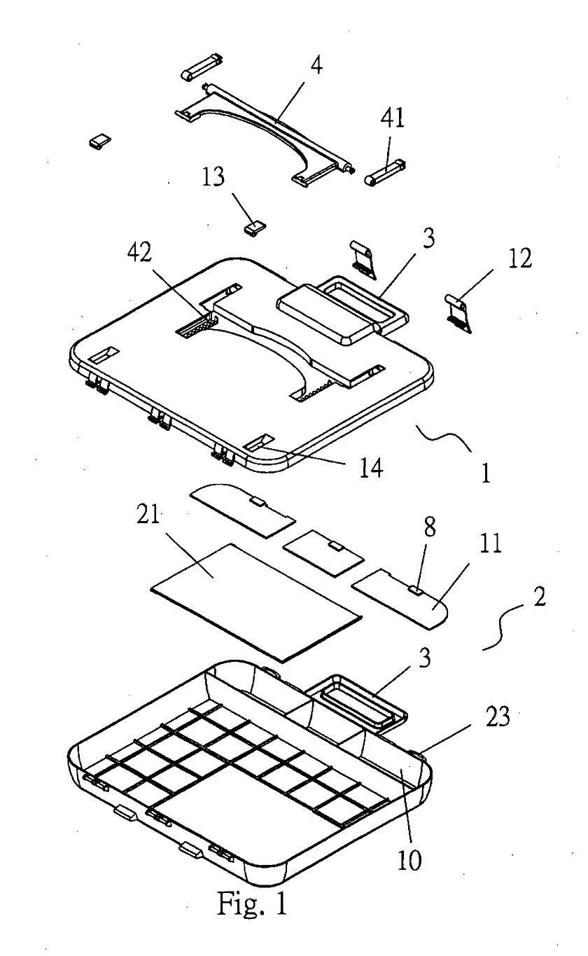

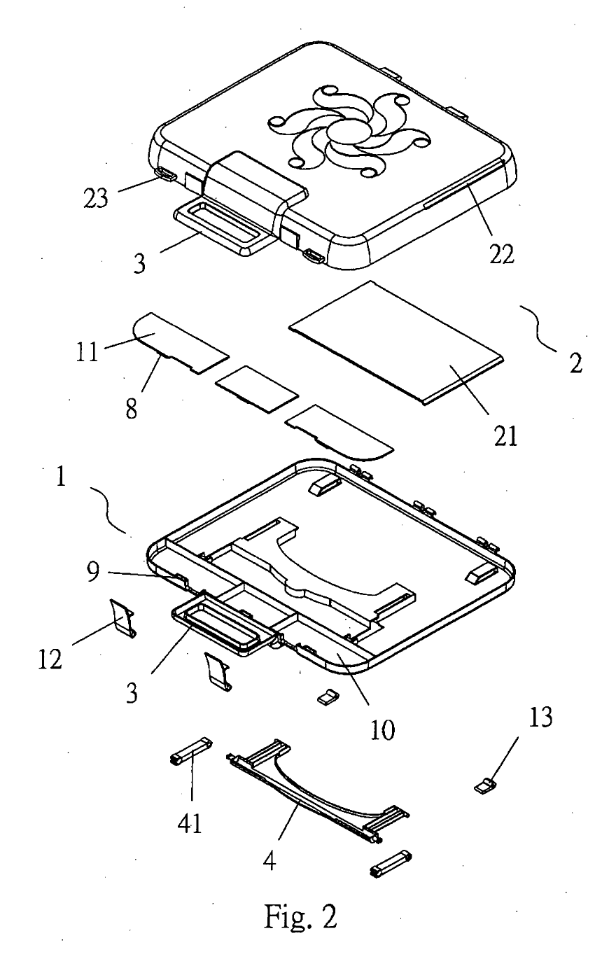

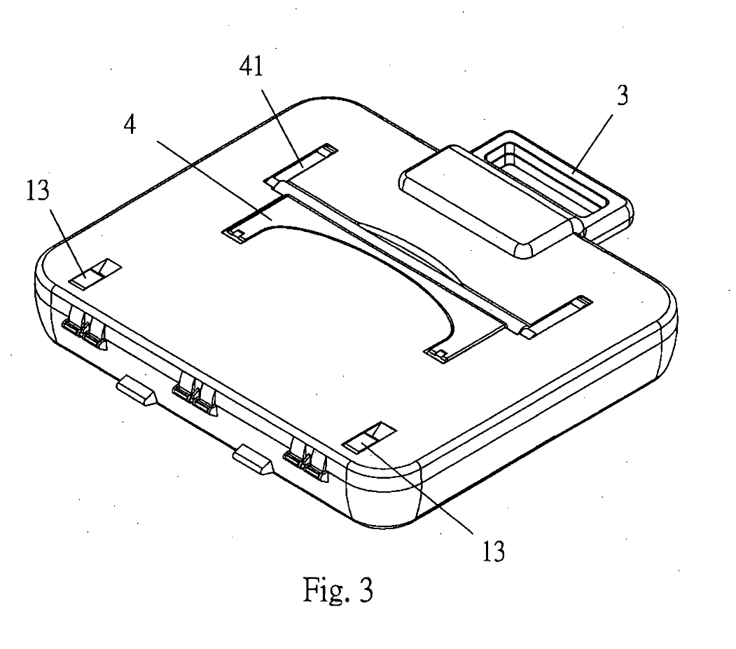

Referring to FIGS. 1, 2 and 3, the present invention includes a first cover 1 and a second cover 2 which are pivotally connected.

At least one receiving groove 10 (in the drawing, three receiving grooves 10 are shown) is formed in a top inner side of each of the first cover 1 and second cover 2. Each receiving groove 10 is covered by a covering plate 11 for isolating the receiving grooves 10 of the first cover 1 and second cover 2.

Each covering plate 11 is installed with an iron sheet 8 so that each covering plate 11 can be absorbed to a magnet 9.

The receiving grooves 10 of the first cover 1 are spaced for receiving different objects, such as signal wires, USB expanders, earphones, microphones, etc.

A supporting plate 4 is installed at a topside of the first cover 1. Each of two lateral sides of the supporting plate 4 is installed with a connecting rod 41 which rests in a slot of a positioning strip 42 for adjusting an orientation of a display screen of a notebook computer.

At least one buckle 12 (in FIG. 1, two buckles 12 are illustrated) serves to combine the first cover I and second cover 2 at tops of the first cover 1 and cover 2.

At least on stop sheet 13 (in FIG. 1, two stop sheets 13 are illustrated) is installed to a recess 14 of the first cover 1.

The receiving grooves 10 of the second cover 2 are spaced for receiving different objects, such as transformers, power wires, mice, etc. A mouse pad 21 is installed in the second cover 2. The mouse pad 21 can be pulled out from a notch 22 of the second cover 2.

A handle 3 is formed at a combining structure of the first cover 1 and the second cover 2.

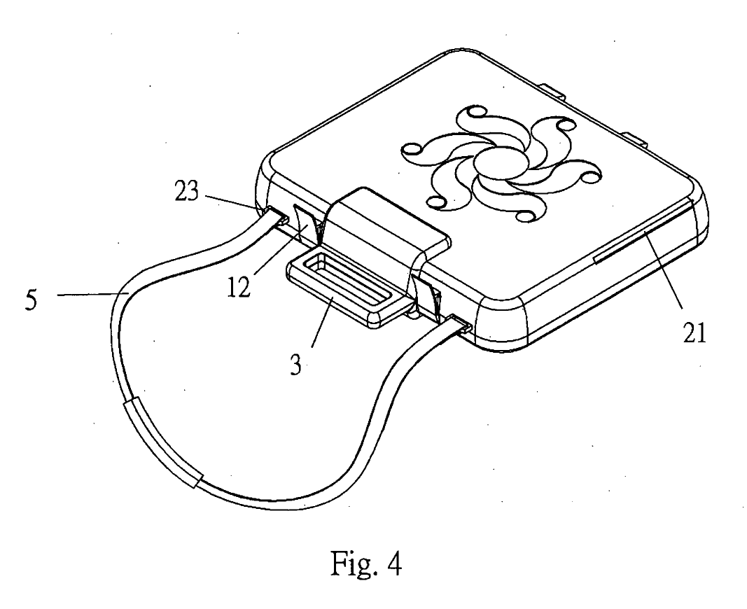

Referring to FIG. 4, it is illustrated that two rings 23 are installed at the top of the combining structure of the first cover 1 and second cover 2. Two ends of a belt are buckled to the two rings 23 so that the user can carry the present invention easily.

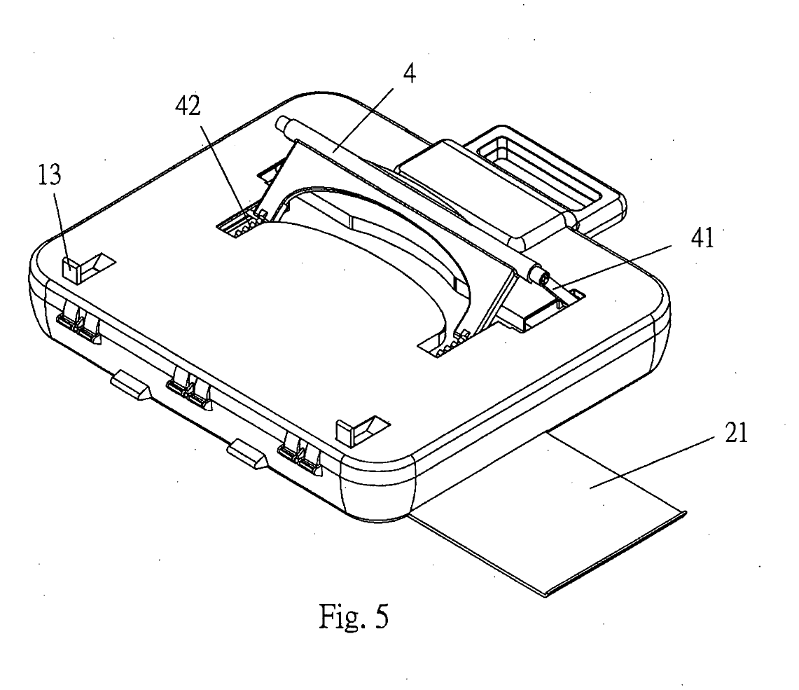

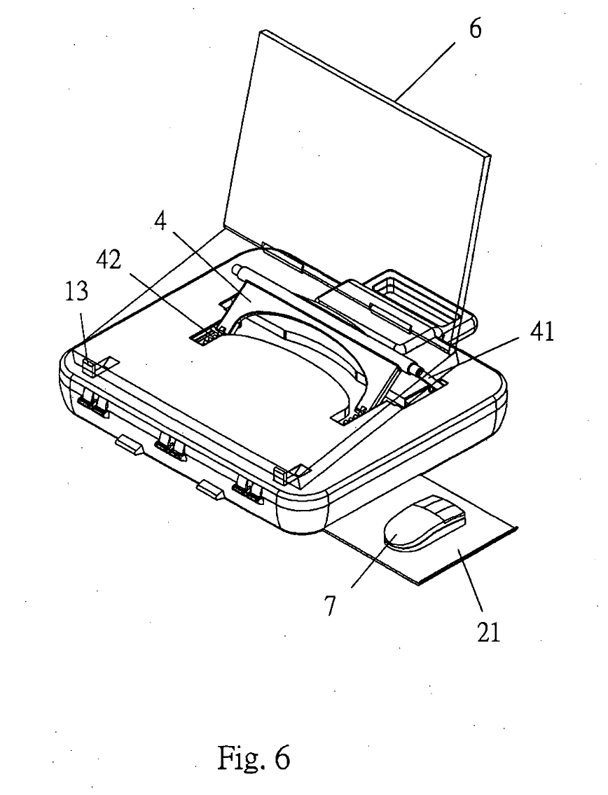

Referring to FIGS. 5 and 6, it is illustrated that each of two lateral sides of the supporting plate 4 is installed with a connecting rod 41 which rests in a slot of a positioning strip 42 for adjusting an orientation of a display screen of a notebook computer. The stop sheets 13 of the first cover 1 can be opened actively for stopping the notebook computer 6. A mouse pad 21 can be pulled out from the lateral side of the second cover 2 for locating the mouse 7 (referring to FIG. 6).

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A multi-functional box for a notebook computer, comprising:
a first cover and a second cover which are pivotally connected as a combining structure;
at least one receiving groove formed in a top inner side of each of the first cover and second cover; each receiving groove being covered by a covering plate for isolating the receiving grooves of the first cover and second cover;
the receiving grooves of the first cover spaced for receiving different objects including signal wires, USP expanders, earphones, microphones; and the receiving grooves of the second cover being spaced for receiving different objects including transformers, power wires, mice;
a supporting plate installed at a topside of the first cover; each of two lateral sides of the supporting plate being installed with a connecting rod which rests in a slot of a positioning strip for adjusting an orientation of a display screen of a notebook computer;
at least one buckle for combining the first cover and second cover at tops of the first cover and cover; and
at least on stop sheet installed to a recess of the first cover.

2. The multi-functional box for a notebook computer as claimed in claim 1, wherein a handle is formed at a combining structure of the first cover and the second cover.

3. The multi-functional box for a notebook computer as claimed in claim 1, wherein a lateral side of the second cover is formed with a notch.

4. The multi-functional box for a notebook computer as claimed in claim 1, wherein a topside of the combining structure is installed with a belt for carrying.

5. The multi-functional box for a notebook computer as claimed in claim 1, wherein each covering plate is installed with an iron sheet so that each covering plate can be absorbed to a magnet;
